(19) United States
(12) Patent Application Publication
(10) Pub. No.: US 2012/0217622 A1
(43) Pub. Date: Aug. 30, 2012

(54) Method for Imparting a Controlled Amount of Stress in Semiconductor Devices for Fabricating Thin Flexible Circuits

(75) Inventors: Stephen W. Bedell, Armonk, NY (US); Devendra Sadana, Armonk, NY (US); Keith E. Fogel, Armonk, NY (US); David Fried, Armonk, NY (US); Paul A. Lauro, Armonk, NY (US)

(73) Assignee: International Business Machines Corporation, Armonk, NY (US)

(21) Appl. No.: 13/467,537

(22) Filed: May 9, 2012

Related U.S. Application Data
(63) Continuation-in-part of application No. 12/784,698, filed on May 21, 2010.

(51) Int. Cl. H01L 29/02; H01L 21/78

(52) U.S. Cl. 257/632; 438/464; 257/E21.599; 257/E29.002

(57) ABSTRACT

Imparting a controlled amount of stress in an assembly comprising a semiconductor circuit on a substrate comprises depositing a tensile stressed metal film stressor layer onto the surface of the circuit. Establishing a fracture region below electrically active regions of the circuit, adhering a foil handle to the assembly and pulling it away from the assembly induces mechanical fracture in the fracture region below the electrically active regions. The mechanical fracture propagates parallel and laterally to the surface of the substrate and below the circuit to produce a thin flexible circuit on a residual substrate. The circuit is under compressive strain that is changed by modifying the stressor layer or residual substrate. Individualized circuits or a circuit may also be defined above the fracture by dividing the circuit into preselected regions with surrounding trenches before fracture. We harvest the circuit(s) by pulling the foil handle away from the assembly.

### RELATED APPLICATIONS

The present application is a Continuation-in-Part application of U.S. patent application Ser. No. 12/784,688 filed May 21, 2010, a Non-Provisional application which claims the benefits of and is based on Provisional Application Ser. No. 61/185,247 filed on Jun. 9, 2009, the contents said Non-Provisional application and said Provisional Application being incorporated herein by reference in their entirety.

### FIELD OF THE INVENTION

The field of the invention comprises processes for controlling stress in a semiconductor device circuit (“circuit”) to enable producing a thin flexible circuit by mechanically inducing not only lateral spalling, i.e., fracture that propagates parallel to the surface of a circuit and below the circuit, but also simultaneous separation of the thin flexible circuit from the substrate.

### BACKGROUND OF THE INVENTION

Integrated circuits are manufactured by first fabricating discrete devices (e.g., field effect transistors [FETs], capacitors, inductors and resistors) monolithically into the surface of a semiconductor substrate, and then patterned dielectric layers followed by metallization layers for connecting the discrete devices into completed circuits. The completed circuits or chips are then packaged in such a manner that they can be further integrated into board and system-level designs, and optimized with respect to thermal management of the completed chip. One such method of improving the thermal characteristics of the completed chip is to remove a portion of the back-side of the semiconductor substrate prior to final packaging. Typically, heat transport through the semiconductor substrate is a major factor in the total thermal impedance of the chip. By chemically or mechanically removing (etching or polishing) a portion of the back-side of the substrate, the thermal impedance of the chip is reduced and the operating temperature is lowered. Etching or mechanical polishing have practical limits as to the amount of substrate material which can be removed, so there remains a need for techniques that permit the fabrication of integrated circuits on extremely thin substrate layers without these limits.

The semiconductor industry developed laboratory scale technology for producing extremely thin substrates in the early 1980's, generally referred to as Silicon On Insulator (SOI) or silicon on sapphire (SOS) technology. SOI technology refers to the use of a layered silicon-insulator-silicon substrate in place of conventional silicon substrates in semiconductor manufacturing, especially microelectronics, to reduce parasitic device capacitance and thereby improve performance. Celler, G. K., Cristoloveanu, S. J App Phys, 93, 4955 (2003). SOI-based devices differ from conventional silicon-built devices in that the silicon junction is above an electrical insulator, typically silicon dioxide (SOI). Similarly, the silicon junction is above a sapphire (aluminum oxide) electrical insulator in SOS structures.

The choice of insulator depends largely on intended application, with sapphire (SOS) being used for high-performance radio frequency (RF) and radiation-sensitive applications, and silicon dioxide (SOI) for diminished short channel effects in microelectronics devices. The insulating layer and topmost silicon layer also vary widely with application Silicon-on-Insulator Technology: Materials to VLSI, Jean-Pierre Colinge, Springer Verlag, 1991, ISBN 978-0-7923-9150-0. The first industrial implementation of SOI was announced by IBM's East Fishkill, N.Y. facility in August, 1998. (http://www-03.ibm.com/press/us/en/pressrelease/2521.wss)

SOI chips enabled development of smaller devices because of their high-performance and low-power characteristics that improve device performance by up to 35percent—translating into faster computers and communications gear. For example, a microprocessor designed to operate at 400 MHz can instead be built using SOI and can achieve speeds of over 500 MHz. But where performance levels are held constant, SOI chips require as little as one-third the power of microchips used in the past. Reducing the power necessary to operate chip circuitry significantly extends the battery life of portable devices, such as mobile computers, personal digital assistants (PDAs), and cell phones.

Additionally, strain engineering has become a common method to extend the performance of CMOS technology as extreme device scaling begins to impede transistor drive current capability. By applying strain to the semiconductor, the charge carriers (either holes or electrons) are transported through the material at higher velocity thus improving drive current independently from scaling. Strain engineering is currently achieved by modifying the material surrounding the transistor active regions so that stress is transferred from the surrounding regions to the body of the device. As the spacing between the devices keeps decreasing, this “local stressor” technique becomes less effective. Also, thin body devices such as extremely thin silicon-on-insulator (ETSOI), or non-planar devices such as FETs do not permit proximity-based strain engineering. The ability to apply strain to a completed circuit independent of transistor geometry would enable strain engineering of emerging CMOS technologies.

### RELATED ART

Bedell et al., United States Patent Application No. 20100311250 teaches a method for manufacturing a thin film direct bandgap semiconductor active solar cell device that comprises providing a source substrate having a surface and disposing on the surface a stress layer having a stress layer surface area in contact with and bonded to the surface of the source substrate. Operatively associating a foil handle with the stress layer and applying force to the foil handle separates the stress layer from the source substrate, and leaves a portion of the source substrate on the stress layer surface substantially corresponding to the area in contact with the surface of the source substrate.

Kawashima, U.S. Pat. No. 8,043,940 describes a method of breaking a semiconductor wafer along modified layers; a method of artificially applying an external force to the semiconductor wafer and a method of utilizing the occurrence of spontaneous breaking. Where an external force is applied, no particular method of applying the external force and no particular direction of application of force are specified.

Okonogi, U.S. Pat. No. 6,323,109 describes an insulation film formed on a single crystal silicon substrate such as hydrogen anneal substrate that is an intrinsic gettering substance and an epitaxial substrate. After conducting hydrogen implantation and heat treatment, voids are formed and the single crystal silicon substrate is cleaved from the structure.

Liao, U.S. Pat. No. 6,365,488 describes a first oxide layer formed over a first semiconductor substrate having implanted ion regions that is bonded to a second oxide layer to form a wafer to complete a SOI insulator wafer having a buried layer structure incorporated t into an integrated circuit.

Behfar, et al. U.S. Pat. No. 6,326,285 describes using a tensile layer and a hydrogen rich region in the substrate of a semiconductor device to fracture the substrate.

Riou, United States Patent Application No. 20110256730 teaches manufacturing SeOI substrates involving the creation of a weakening area in the thickness of an initial substrate, a so-called donor substrate, and a fracture at this area, after assembling the donor substrate with a receiving substrate. This SeOI type thus comprises at least two layers, one from the donor substrate, the other one from the receiving substrate.

Gonzalez, U.S. Pat. No. 6,706,608 teaches a substrate cleaving process which involves heating the substrate to a temperature sufficient to fracture the substrate at the damaged region, followed by separation of the substrate at the damaged region. The present invention does not create a damaged region and does not include implantation.

Bedell, et al., U.S. Pat. No. 7,935,612 describes a method for layer transfer using a boron-doped silicon germanium (SiGe) by forming a boron-doped SiGe layer on a bulk silicon substrate; forming an upper silicon (Si) layer over the boron-doped SiGe layer; hydrogenating the boron-doped SiGe layer; bonding the upper Si layer to an alternate substrate; and propagating a fracture at an interface between the boron-doped SiGe layer and the bulk silicon substrate.

Foumell et al., United States Patent Application No. 20110201177 teaches a process for forming a thin film of a given material that includes providing a first substrate having, on the surface, an amorphous and/or polycrystalline film of the given material and a second substrate is bonded to the first substrate by hydrophobic direct bonding (molecular adhesion), the second substrate having a single-crystal reference film of a given crystallographic orientation on the surface thereof. A heat treatment is applied at least to the amorphous and/or polycrystalline film, where the heat treatment causes at least a portion of the amorphous and/or polycrystalline film to undergo solid-phase recrystallization along the crystallographic orientation of the reference film, where the reference film acts as a recrystallization seed. The at least partly recrystallized film is then separated from at least a portion of the reference film.

Miiieczkowski et al., United States Patent Application No. 20110115058 describe a saw and a flexible tape to separate individual die from one another and the use of “crack stop’” regions to suppress substrate cracking after substrate thinning.

### SUMMARY OF THE INVENTION

The present invention comprises structures, articles of manufacture, processes and products produced by the processes that address the foregoing needs, and provides a method for reducing the thickness of circuits in order to allow them to operate at lower temperatures, lower power consumption, and optimum speeds. We achieve this by using a tensile stressor layer having a controlled amount of stress and a controlled thickness, which we deposit on the surface of an individual or an array of processed or completed circuits on a substrate and then mechanically induce lateral fracture or spalling at a depth within the substrate and below the electrically active regions of the circuit in order to reduce the thickness of the circuit device without chemical or mechanical polishing.

The stress value and the thickness value combination that permits controlled spalling depends on the material used as the stressor, as well as the mechanical properties of the substrate material. Approximate conditions for the case of a Ni film as the stressor layer are described in paragraph [0027] of US 2010 0311250 US1 by Bedell et al.

Mechanically inducing lateral spalling also separates the circuit from the underlying substrate. In another aspect of the invention, we remove individualized circuits without cutting or dicing by dividing them before the fracture step into preselected regions defined by trenches surrounding them. Pulling on a foil handle operatively associated with, e.g., adhesively secured to the surface of the circuit or substrate not only induces the mechanical fracture and separation of the thin circuits but also enables harvesting the individualized circuits.

The method as described above is used in the fabrication of integrated circuit chips. The resulting integrated circuit chips can be distributed by the fabricator in raw wafer form (that is, as a single wafer that has multiple unpackaged chips that can be harvested as described herein), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Examples of circuits in addition to those described above comprise, micro-electro-mechanical (MEMS) components, passive filters, detector arrays, photovoltaic displays, and the like or SiGe or III-V electronic devices, or C or Si or Ge devices, or opto-electronics.

### BRIEF DESCRIPTION OF THE DRAWINGS

The accompanying drawings also set out the invention and are incorporated in and constitute a part of the disclosure along with this specification and are included to illustrate various embodiments of the invention and together with this written description also serve to explain the principles of the invention. These drawings, however, are not necessarily drawn to scale.

FIG. 1 comprises a series of side elevations in cross-section illustrating the process of the invention for fabricating thin flexible circuits.

FIG. 2 comprises a graph depicting the results of Raman Spectroscopy of a completed circuit produced according to the invention.

FIG. 3 comprises a photomicrographic plan view of spalled M1 circuits of the invention.

FIG. 4 comprises a graph showing features of the circuits of the invention before spalling and after spalling.

FIGS. 5 and 6 comprise photomicrographs of cross-sections of polished M1 circuits of the invention about ˜15 μm total substrate thickness, illustrating recovery of the original M1 surface as well as unchanged device characteristics before and after spalling.

FIG. 7 comprises a side elevation in cross-section of a scanning electron micrograph (SEM) of a polished M1 device produced according to the process of the invention.

### DETAILED DESCRIPTION

To achieve these and other advantages, and in accordance with the purpose of this invention as embodied and broadly described herein, the following detailed features can be employed in various forms.

The specific processes, materials compounds, compositions, and structural details set out herein not only comprise a basis for the claims and a basis for teaching one skilled in the art to employ the present invention in any novel and useful way, but also provide a description of how to make and use this invention.

The invention comprises a method for imparting a controlled amount of stress in a semiconductor circuit to enable inducing a mechanical fracture or spalling, in which a crack is propagated parallel to the surface of a semiconductor substrate below the circuit and laterally to produce a thin flexible circuit. A reduction in the thickness of the circuit allows it to operate at lower temperatures, lower power consumption, and optimum speeds.

Modes of fracture that are much more common in brittle substrates or brittle films generally lead to cracks propagating with a directional component perpendicular to the substrate surface. This leads to substrate breaking or chipping, or cracking in the case of brittle films. Spelling mode fracture is a unique among the modes of brittle fracture in that the crack propagates parallel to, and below, the surface. This is due to the presence of both type I stress (opening mode) and type II stress (shear mode) caused by the tensile stressed surface stressor layer. Fracture tends to propagate where the shear stress is zero. In the mixed-mode configuration (type I and type II), the shear stress can be made to be zero at a depth within the substrate.

In practicing our invention, we deposit a stressor (typically a tensile stressed metal film) having a thickness and controlled amount of stress and which must have a high fracture toughness value and preferably a high yield stress value onto the surface of an individual or array of processed or completed circuits on a substrate.

Metals typically have a high fracture toughness value (K_{IC}) compared to brittle materials (such as the semiconductor materials Si, Ge, GaAs, etc.) and the high fracture toughness of the metal helps minimize cracking of the stressor layer. The stressors comprising metals that can be used for controlled spalling according to our invention possess an intrinsic stress of between about 200 to about 800 MPa without yielding. Therefore, stressors comprising metals such as Ni, Cr, Ti and others with high yield stress values are useful for controlled spalling according to our invention. Softer metals such as Al or Cu can be used, in principle as stressors, if lower values of stress are employed.

We also define the metals used according to our invention as high fracture toughness metals having K_{IC} values in the range of about 5 to about 50 MPa*m^{1/2} whereas brittle ceramics and most semiconductors have K_{IC} values less than about 1.

Adhesively applying a foil handle to the tensile stressor layer or substrate and pulling it away from the stressor layer or substrate helps initiate a surface crack and mechanically guides fracture or spalling at a depth below the electrically active regions of the circuit, resulting in reduced circuit thickness without chemical or mechanical polishing. This separates the circuits from the underlying substrate. Adjusting the stressed metal film thickness and stress ensures proper crack or fracture trajectories through preferred regions such as below or at buried oxide interfaces, weakened layers and the like in the circuit. As an example, in one embodiment we adjust the Ni thickness and stress to specified values to ensure proper crack or fracture trajectory.

The required stress and thickness combination of the stressor layer to induce surface spalling for the case of a Ni film as the stressor layer are described in paragraph [0027] of US 2010 0311250 US1 by Bedell et al. As an example, for the case of a Si substrate using a Ni stressor layer, a Ni layer thickness of approximately 6 μm with an intrinsic tensile stress of approximately 500 MPa will induce fracture at a depth of approximately 20 μm below the surface of the substrate. If a shallower fracture is required, then a thinner Ni layer can be used, but a larger stress value may be required (as taught in 2010 0311250 US1 by Bedell et al.).

Spalling can be made to occur at a pre-selected depth within the substrate as indicated above because the equilibrium fracture depth will tend to occur where the shear stress (K_{II}) is zero. Alternatively, if the fracture toughness at a given depth is made to be lower than the substrate K_{IC}, fracture can preferentially occur in that location (non K_{II}=0 spalling). Such can be the case if the substrate to be spalled contains a layer that is mechanically weakened compared to the surrounding substrate material.

We have observed that in certain silicon-on-insulator (SOI) structures, fracture will preferentially occur at or within the buried oxide layer. Generally this happens when the buried oxide formation has been compromised in some way. A SOI wafer containing a buried insulator layer (BOX) can be formed using the Smart-Cut process whereby a silicon wafer with a surface SiO₂ layer (donor wafer) is implanted with H₂, bonded to another Si wafer (handle wafer), and thermally annealed to separate an upper portion of the first wafer from the lower portion of the first wafer. This step is usually followed by a high-temperature (˜1100° C.) bond anneal to chemically react the bonded SiO₂/Si interface. If this bond anneal is reduced (in time or temperature) then the bond strength (and thus local K_{IC}) will be lower than the strength of the surrounding substrate.

Likewise, if the bonding between the SiO₂ and the substrate is compromised chemically, it will result in a locally reduced K_{IC} at or within the buried insulator. This can be accomplished, for example, by depositing a layer of Si₍₁₋ₓ₎Ge₍ₓ₎ alloy either on the handle substrate (i.e., the substrate to which the foil handle is secured) prior to bonding, or on the donor wafer prior to oxide deposition/growth. The SiGe can be deposited in any manner known in the art; for amorphous or polycrystalline layers, sputtering, evaporation or other PVD methods are sufficient; for single-crystal layers chemical vapor deposition at any pressure is sufficient as well as molecular beam epitaxy (MBE). The presence of Ge at the SiO₂ interface has been observed to weaken the buried oxide interface and lead to preferential spalling along the BOX interface. The Ge content of these layers can be from about 5 atomic percent Ge up to pure (>99%) Ge. The higher the Ge content, the lower the SiO0₂/SiGe bond strength will be. In all these cases the atomic bonding at or within the buried oxide layer has been compromised (reduced) compared to a thermally-grown SiO₂/Si structure.

In another embodiment we remove individualized circuits above the fracture without cutting or dicing them by dividing them before fracture into preselected regions defined by trenches surrounding them. We also harvest the circuit or a plurality of them when pulling the foil handle away from the substrate or circuit.

The depth of the trenches is substantially similar to the anticipated fracture depth induced by the tensile stressor layer. The anticipated fracture depth is the depth at which fracture is desired. In the case of spalling at the equilibrium fracture depth (the absence of weakened layers), the depth of fracture (and thus the trenches) can be computed by a complete stress analysis of the multilayer crack loading configuration using either finite element analysis (FEA) or analytical analysis (J. W. Hutchinson and Z. Suo, “Mixed mode cracking in layered materials,”Adv. Appl. Mech., vol. 29, pp. 63-191, 1992). Roughly, the fracture depth is approximately 2 to 3 times the stressor layer thickness for many metal stressor/semiconductor substrate combinations. Typical stressor thickness range is from about 2 to about 20 microns and thus the equilibrium fracture depth ranges from about 4 to about 50 microns. In the case where weakened layers are employed (such as the aforementioned compromised bonding approach), the trench depth should be made to coincide with the weakened layer depth.

We deposit the tensile stressor layer onto the surface of the region-containing substrate (either selective deposition in the preselected regions or blanket layer deposition) so that the trench serves as an efficient initiation and termination point of fracture and the preselected regions can be removed independently from each other.

The preselected regions of completed circuits possess residual strain due to the stress transfer from the upper tensile stressor layer to the circuit layer. We control the magnitude and sign of this strain, by post circuit stressor layer removal processing prior to bonding and packaging.

The circuit layer will, in general, be under compressive strain because tensile stressor layers are used to induce surface layer removal (spalling). The amount of compressive strain in the circuit layer will increase as the thickness of the circuit layer is reduced (substrate thinning),and the amount of compressive strain in the circuit layer will reduce as the thickness of the tensile stressor layer is reduced (stressor thinning). We therefore control the amount of compressive strain in the circuit layer by etching either the substrate layer or the stressor layer. In another embodiment we completely remove the tensile stressor layer followed by deposition of a compressive stressor layer to convert the compressive strain in the circuit layer into tensile strain. The advantage of converting the naturally compressively stressed spalled semiconductor layer into tensile stress is one of design generality. Holes and electrons respond differently to compressive or tensile stress as well as biaxial and uniaxial stress. For biaxial stress, electron low-field mobility is greatly enhanced by tensile strain. Depending on the substrate material (Si, GaAs or Ge) and the circuit technology (MOS, BJT, HEMT), either compressive or tensile stress will be desired. A compressive stressor material that can be deposited after the tensile stressor is removed can be a compressively stressed Silicon Nitride (Si₃N₄) or silicon oxide (SiO₂) layer deposited by CVD techniques capable of providing compressive stress (e.g., PECVD), or even compressive stressed metal layers. Usually, higher atomic number metals such as W can be sputter deposited with compressive stress. Typical stress values can be from about 50 to about 1000 MPa or about 100 to about 800 MP. Thickness of the compressive stressor layer can be from about 0.5 μm to about 15 μm, or about 1 μm to about 10 μm.

Barrier metals (such as Ti and its equivalents, e.g., the equivalents described herein) between the upper portion of the fabricated circuits and the deposited stressed metal layer enables the stressed metal layer to be selectively removed from the surface after the circuit or circuits have been fractured and removed from the substrate. Buried insulator layers, such as oxide layers that have a fracture strength less than that of the substrate material cause fracture to preferentially propagate along the buried insulator interface or within the insulator layer. Engineered cleaving layers at a depth below the active regions of the circuits within the substrate provide preferential cleaving regions such as stressed epitaxial layers or damaged and weakened regions. The portion of the substrate where fracture is to occur can be chosen to have a crystallographic orientation that promotes easy fracture in a direction parallel to the surface, e.g., <111> surface orientation for the elemental diamond cubic lattices (C, Si, Ge), and the <110> surface orientation for the compound semiconductors (III-V), e.g., GaAs, and the like. Generally, when the surface orientation of Si or Ge substrates is <001>, the direction of controlled spalling along surface can be in any of the [100] surface directions (45° to the natural fracture direction) to minimize the roughness of the fractured surface.

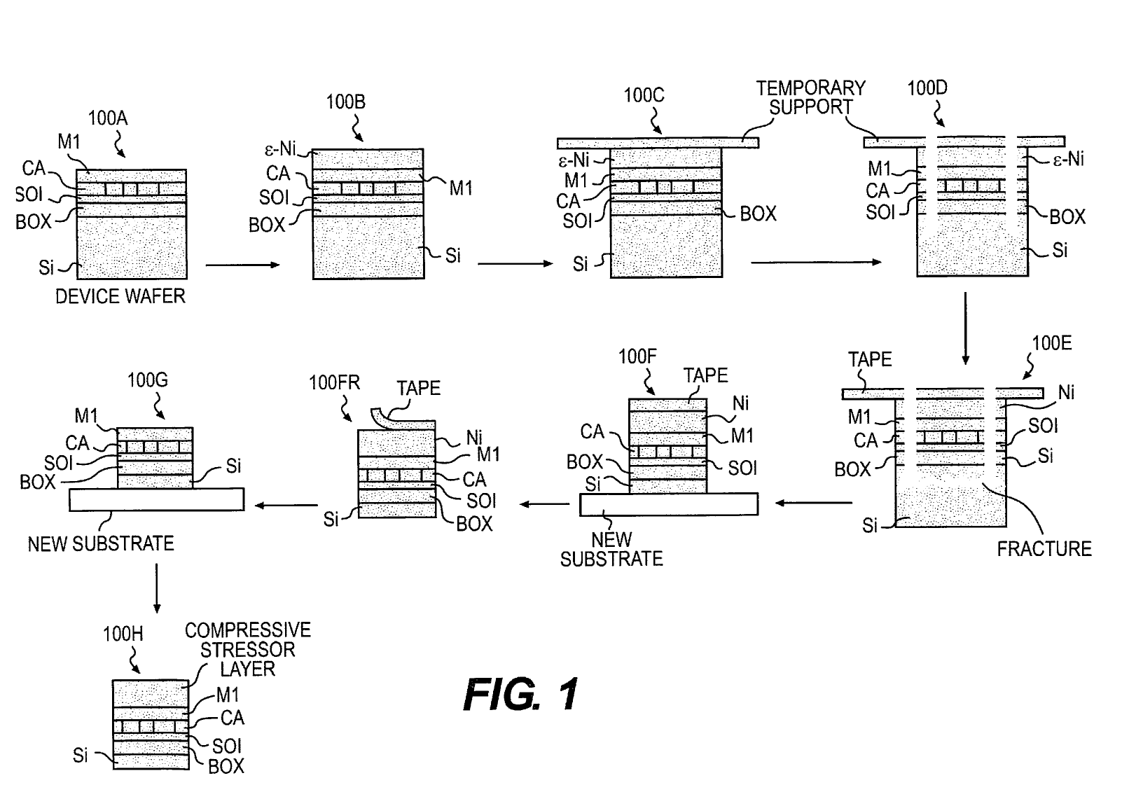

FIG. 1 illustrates process steps showing construction of a circuit of the invention. In FIG. 1 we show various layers of these circuits as follows. “BOX” comprises a buried oxide layer which can be any electrically insulating layer comprising Si3N4, high-k dielectrics, semi-insulating epitaxy layers and the like. “SOI” in FIG. 1 comprise an exemplary material representing the circuit fabricated not only on a silicon on insulator substrate, but also any substrate, e.g., bulk, Si, Ge III-V, GaN, and their art known equivalents such as sapphire. “CA” comprises Contact Apertures, i.e., a circuit level that connects the metallization level to the actual transistors. The layer is comprised of vias, studs (metal contacts to devices) and the like such as any circuit level connecting one electrical layer to another. “M1” comprises metal layer 1, a circuit level metallization to connect individual devices into circuits. There can be (and usually are) multiple levels of wiring (M2, M3 . . . ) The adhesion promoter described herein is deposited on top of this layer (or if there are multiple layers of wiring such as M2, M3, and the like, the topmost layer). “M1” equivalents comprise any electrically contactable surface layer, usually, but not necessarily, planarized. The stressor layer comprises Ni or its equivalents such as Ti, TiNi, Fe, Co, NiCo, FeNi, Mo, or any metal capable of sustaining over about 100 MPa without yielding. As noted, “M1” comprises a metal layer to connect the circuit elements, even though limited connectivity exists in reality at the device level, but most interconnection is done at metal level 1 (M1) or higher metallization levels.

The circuits of the invention in FIG. 1 comprise spalled circuits or chiplets in a series of side elevations in cross section 100A through 100H. Side elevation 100A comprises a device wafer having a circuit for processing according to the invention, whereas side elevation 100B comprises an illustration of the circuit after metal deposition using Ti as an adhesion promoter and an etch stop layer, and Ni as a stressor layer. Other adhesion promoters that may be employed comprise at least one of Ti/W, Ti, Cr, or Ni As illustrated in side elevation 100C we adhesively apply a foil handle, typically a plastic (polyimide, PVC, PO, PET, PEEK, etc.) foil, that may be released from the stressor layer by a thermal, chemical or optical process.

Side elevation 100D illustrates the process of physically defining the chipiet by scribing the circuit or by laser ablation. We can perform this step prior to the application of the foil handle in stead of at this juncture.

In side elevation 100E we illustrate the application of force to allow fracture to release the chiplet onto the foil handle. We can also release the whole wafer level if the tape is applied after chiplet definition.

Side elevation 100FR illustrates removal of the handle layer after the chip or chiplet has been harvested. As noted, we remove the handle layer from the stressor layer (in this instance, the Ni layer) by applying chemical, thermal, or UV energy to it after employing the handle to induce fracture of the thicker Si base and separate the chip or chiplet from the thicker Si base, as shown in Fig. 100E. In some embodiments we apply the foil handle only over the chiplet regions of the circuit, and not the whole wafer, or we cover the rest of the wafer/chips and the handle layer is selectively adhered to the area of a single chip.

Side elevation 100F illustrates transfer of the separated circuit from 100E onto a conventional substrate or a substrate optimized for a particular application, e.g., thermal sink, or flexible substrate. Prior to bonding to this substrate the circuit can be thinned by any means known in the art (wet etching, dry etching, or mechanical or chem.-mechanical polishing or lapping) to optimize either the residual strain in the circuit and/or its thermal properties. In one embodiment (not shown) we remove residual Si by etching in tetramethyl ammonium hydroxide solution or using xenon diflouride dry etching from the bottom of the circuit of 100F thereby transferring residual stress in the structure to the circuit level. After spalling the strain in the metal stressor layer is in equilibrium with the strain in the spalled layer, i.e., the in-plane forces must balance.

Typical strain in a 20 μm thick spalled Si layer can be from about 0.05 to about 0.1% compressive. As the substrate is thinned, the metal stressor contracts to thereby increase the compressive strain in the spalled layer. The maximum value is the limit where the metal stressor is substantially stress-free and has transferred nearly all strain to the ultra-thin spalled layer. For a 600 MPa Ni layer this value is about 0.21% and for 900 MPa Ni the maximum strain is about 0.31%. If more compressive strain is needed, an additional tensile stressed layer can be deposited on the thinned residual substrate surface prior to bonding.

The final thickness of the spalled layer (e.g., Si) after thinning depends on the application, for flexibility, thinner is usually better. We have demonstrated final semiconductor thickness of a functional SOI circuit down to about 5 nm (e.g., spalled Si, with a remaining buried oxide layer intact). If there is no BOX isolation, then the final thickness will be limited by the maximum depth of active regions of the devices (junctions, capacitors, etc.). Typical spalled substrate thickness (e.g. Si) range from about 40 μm down to about 1 nm, or about 30 μm to about 5 nm. Side elevation 100G shows the chiplet with the foil handle removed, and with the metal stressor layer removed by etching.

Thus, the present invention provides a method for removing preselected regions of completed circuits from the surface of a host substrate, where the preselected regions of completed circuits possess residual strain due to the stress transfer from the upper stressor layer (used to remove the circuit layer) to the circuit layer. The magnitude and sign of this strain can be controlled by a post circuit layer removal processing. The circuit layer will, in general, be under compressive strain because the tensile strained layers are used to induce surface layer removal (spalling). The amount of compressive strain in the circuit layer will increase as the thickness of the circuit layer is reduced (substrate etching), and the amount of compressive strain in the circuit layer will reduce as the thickness of the tensile stressor layer is reduced (stressor etching). In a further embodiment we completely remove the tensile stressor layer followed by deposition of a compressive stressor layer to convert the compressive strain in the circuit layer into tensile strain. We illustrate this in Fig. 100G showing complete removal of the Ni tensile layer and Fig. 100H comprising a side elevation in cross section of a circuit produced by deposition of a compressive stressor layer on the device of Fig. G, such as a silicon nitride (Si₃N₄) or silicon oxide (SiO₂) compressive stressor layer deposited by CVD techniques capable of providing compressive stress (e.g., PECVD). Also, this compressive stressed metal layer may comprise a sputter deposited higher atomic number metal such as W.

The thickness of the layers has an affect on the device and the process of manufacturing it. We have previously described some parameters for the thickness of the spalled Si.

The buried oxide layer thickness (BOX layer, present when the circuit is SOD ranges from about 10 μm down to about 1 nm, or about 1 μm down to about 5 nm. The SOI(Silicon-on-insulator) thickness of the entire substrate (upper Si layer+BOX+lower substrate) is usually between about 100 μm and about 1000 μm thick, or about 800 μm to about 300 μm.

The CA (contact layer) thickness ranges from about 50 nm to about 1 μm, or about 100 nm to about 500 nm. It contains patterned metal (with oxide and nitride layers) that connects to the active electrical devices on the wafer surface.

M1 (the M layer or “interconnect layer”) typical thickness ranges from about 50 nm to about 1 μm, or about 100 nm to about 500 nm. It contains patterned metal (with oxide and nitride layers) to connect devices together into circuits. In one embodiment, we employ multiple layers of metallization.

The Ni stressor layer used to induce controlled spalling can be any metal or combination of metal/handle combinations previously specified in Bedell et al., US 2010 0311250 US1.

As previously noted we may impart permanent biaxial strain in the completed circuit to Improve charge carrier mobility in completed circuits. We impart permanent biaxial strain in the completed circuit by changing the physical size of it (stretching [tension], or squeezing [compression]) in both the x-and y-directions. This occurs in the step illustrated in 100E, as soon as the spalled layer is free from the host substrate.

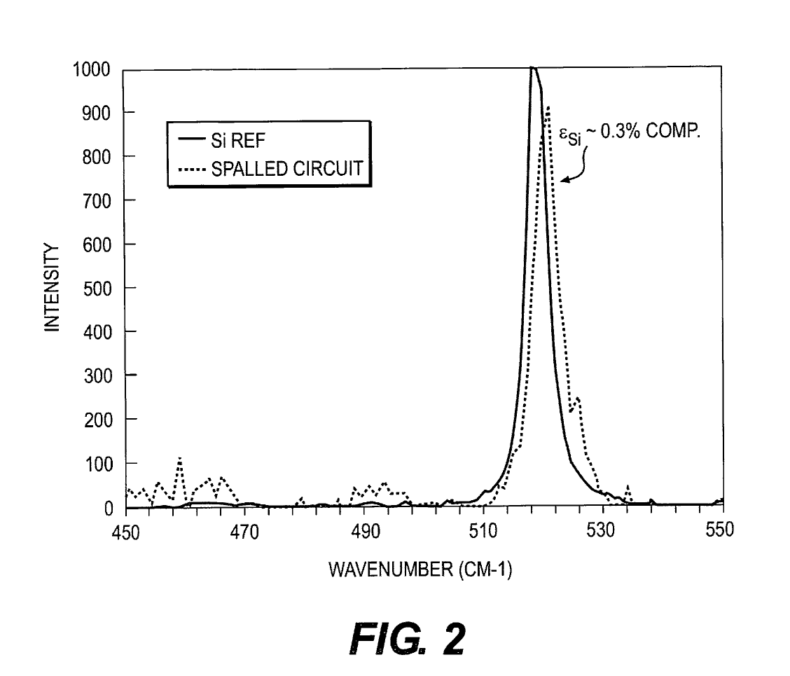

FIG. 2 comprises a graph depicting the results of Raman Spectroscopy of a device of FIG. 1 where the Raman Spectroscopy is of a completed circuit through M1 after spalling, substrate etching and bonding to a glass substrate. Raman peak shift indicates 0.3% compressive strain in the device Si layer; which agrees well with theoretical prediction assuming stress transfer from Ni to thin substrate.

FIG. 2 shows successful transfer of compressive stress to a circuit produced according to the invention. This illustrates the benefits to the circuit provided by the invention, such as for example higher speed, improved power/performance tradeoff and the like.

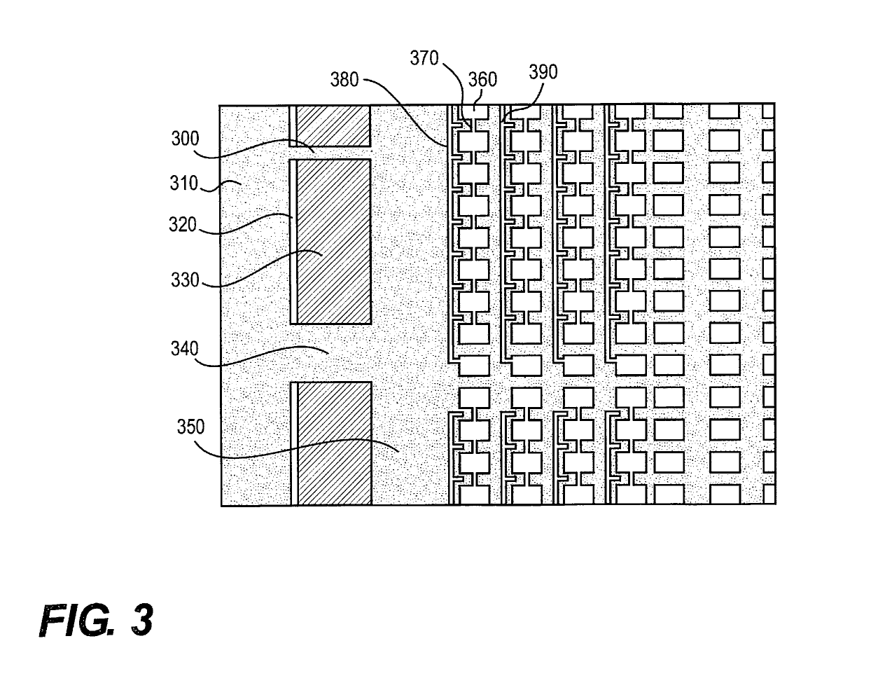

FIG. 3 comprises a photomicrographic plan view of spalled M1 circuits on tape wherein 310, 340, 350 are all shallow trench isolation regions (oxide to electrically isolate devices); 300, 320, 330 all represent some typical electrical test structure or arrays thereof; 380 is a common gate connection to an array of p-channel field effect transistors (pFETs); 370 is the channel region of a pFET and 360 is one of the source/drain connection pads to the FETs; 390 is the same as 380.

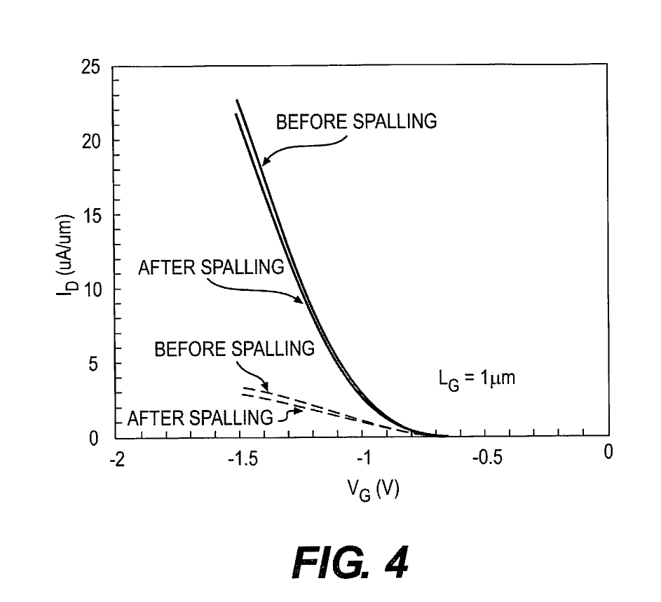

FIG. 4 comprises a graph showing the measured drain current I_{D} (in microamps per micron) versus gate voltage V_{G} (in volts) of a pFET before spalling and after spalling, mounting to glass, handle layer removal, Ni stressor removal, and Ti adhesion layer removal. The gate length L_{G} is 1 μm. The data indicate that the material quality is not compromised after spalling. No substrate thinning was performed before mounting the spalled circuit.

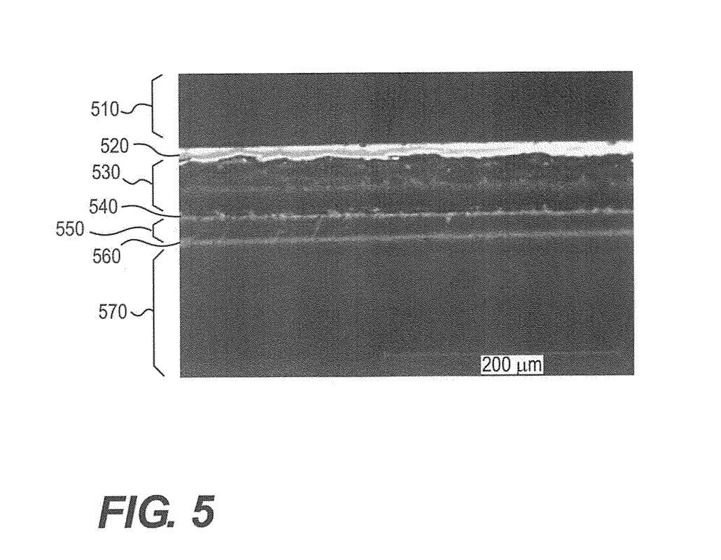

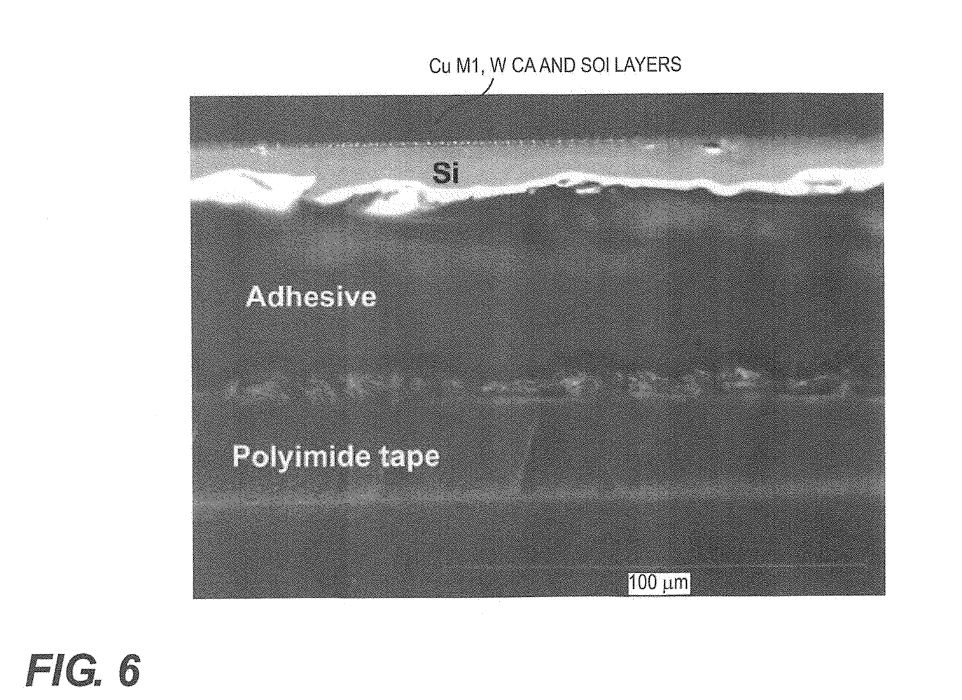

FIGS. 5 and 6 comprise photomicrographs of spalled circuits that were mounted in epoxy, cross-sectioned and polished for imaging. About 15 μm total substrate thickness is shown and illustrates the recovery of the original metallization surface. FIG. 5 comprises a low magnification image of the epoxy, mounted, sectioned, and polished sample of a spalled circuit of the invention showing circuit 510; a spalled circuit layer 520 with handle and stressor removed; an adhesive layer of tape 530 to which the spalled circuit was initially mounted; a boundary 540 between adhesive layer of tape and backing material of tape (polyimide); polyimide backing of tape 550; the surface of the tape (polyimide) 560; and polished epoxy 570 below the mounting tape.

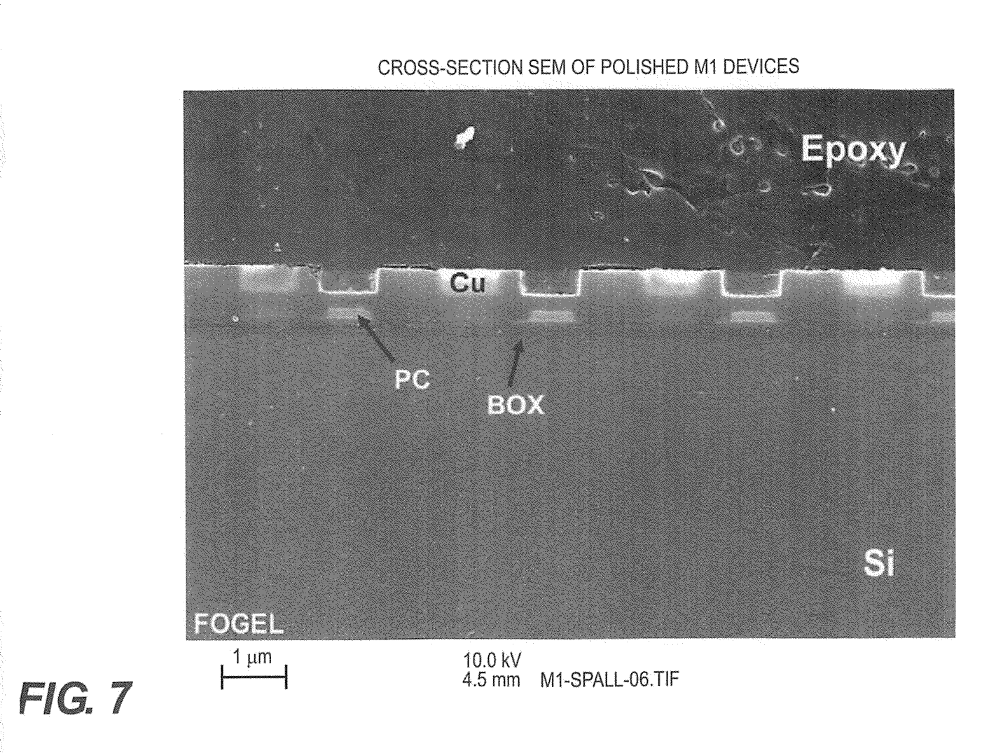

FIG. 7 comprises a side elevation in cross-section of a scanning electron micrograph (SEM) of a cross-sectioned and polished spalled circuit produced according to the process of the invention where component “PC” in the photomicrograph comprises an electrically active semiconductor material (Si in this case).

Thus, in one embodiment the invention comprises a stressed thin film circuit comprising a single crystal or polycrystalline material, alloy, or compound (any orientation) layer less than about 20 microns thick (thin layer). The entire circuit is fabricated prior to bonding to a substrate.

Flexibility is provided in the circuit by a total circuit thickness less than about 20p The relationship between maximum flexibility (minimum radius of curvature before fracture) and the thickness of the circuit layers (either single semiconductor layer or multiple semiconductor layers that are mechanically coupled) can be estimated using mechanical models (A. W. Blakers and T. Armour, Solar Energy Materials and Solar Cells, Vol. 93, 2009, p. 1440).

The circuit is fabricated by a “controlled spalling” process that requires deposition of only thin low-cost stressor layers on the circuit and layer.

In one embodiment the “handle” layer comprises means different than the stressor layer to initiate and propagate the spalling process. This allows for better fracture control and more versatility in handling the circuit layer. A metal layer beneath the stressor layer is optional and serves as an adhesion layer. Certain metals such as Cr, Ti, and other metals and alloys have excellent adhesion properties and can be used in situations where the stressor layer has poor adhesion to the surface of the circuit. Referring to FIG. 1, one or more metal layers, e.g., Ni are deposited on a circuit (e.g., a single crystal semiconductor supporting an array of FETs capacitors, and resistors connected to one another) to a thickness that is less than that required for spontaneous spalling (at room temperature, about 20° C.), but thick enough to permit mechanically assisted spalling using an external load. An example of an external loading technique that successfully leads to controlled spalling is to adhere a foil handle (handle layer) to the surface of the metal which is operatively associated with the metallurgically bonded layers to form a metal/source substrate, followed by pulling the foil handle from the substrate to remove the thin surface layer from the source substrate as well. The foil handle (i.e., handle layer is required to be flexible, and should have a minimum radius of curvature of less than 30 cm. If the foil handle is too rigid, the spalling process is compromised. In one embodiment the foil handle comprises a polyimide.

The process and article of manufacture of the present invention have distinct advantages over the spontaneous spalling of the prior art in four respects; first, the entire process can be completed at room temperature allowing for the removal of completed circuits; second, the lower thermal budget reduces energy costs to produce the thin circuit; third, spalling can be performed at a time and in a manner of convenience rather than spontaneously, allowing more versatility in processing steps; and fourth, the thickness of the removed circuit substrate can be controlled by adjusting the thickness of the stressor layer. By contrast, in the spontaneous process the stressor layer must be thick enough to induce self-initiation, which does not allow for thinner stressor layers that would produce thinner removed layer substrates

In one aspect, the thin stressor layer or layers, singly, or in combination are used at a thickness below that which results in the spontaneous spalling of the source substrate. The condition that results in spontaneous spalling is related to the simultaneous combination of the stressor layer thickness value and stress value, as well as the mechanical properties of the source substrate. At a given stressor layer thickness value, there will be a stress value above which spalling will occur spontaneously. Likewise, at a given stressor layer stress value, there will be a thickness value above which spalling will occur spontaneously. An approximate guide for the stressor layer thickness value at which spalling becomes possible for the case where the stressor layer is substantially comprised of tensile strained Ni is given by the relation t*=[(2.5×10⁶)(K_{IC}^{3/2})]/σ², where t* is the thickness value (in units of microns, μ) of stressor layer 6 at which controlled spalling becomes possible, K_{IC} is the fracture toughness value of the source substrate 2 (in units of MPa·m^{1/2}), and σ is the magnitude of the stress value in stressor layer 6 (in units of MPa, or megapascals). If the stressor layer thickness is greater than the value given by t* by approximately 50%, then spontaneous spalling may occur. In another aspect, the thickness may be anywhere from about 1μm to about 50 um, or from about 3 um to about 30 um, or about 4 um to about 20 um thick. The thin stressor layer or layers comprise a metal layer such as Ni as illustrated in, but this comprises only one embodiment of this aspect of the invention. Other embodiments include multiple thin stressor layers, e.g., up to about three, or about four, or about five metal layers, or more, provided that when taken together, they substantially fall within the thickness limits set out above. As noted before, in one embodiment, the thin stressor layer or layers comprise a low-cost thin stressor layer or layers.

Selection of the thin stressor layer or layers does not have to be based on the difference between the coefficient of thermal expansion of the stressor layer or layers and the coefficient of thermal expansion of the source substrate for promoting spontaneous spalling as in the prior art, where spalling is effected by cooling the structure from an elevated temperature (about 900° C.) to a lower temperature. The present invention does not rely on spontaneous spalling but rather the use of mechanical force, and controlled fracture at substantially room temperature (about 20° C.) to separate the thin stressor layer or layers from the source substrate and remove a thin circuit region of controllable thickness from the source substrate. The thickness of the circuit layer in FIG. 1 from the source substrate is roughly twice the thickness value of the combined thickness values of stressor layer and adhesion layer, e.g., Ti. By controlling the amount of strain in the stressor layer the operable thickness value (t*) of stressor layer can be chosen to remove a controlled thickness of exfoliated circuit layer. For example, if an exfoliated circuit layer having a thickness value of Si<111> was desired to be approximately 8 um, then a Ni stressor layer would need to be approximately 4 um thick.

By using the K_{IC} value for Si<111> (0.82 MPa·m^{1/2}) the expression for f above can be used to calculate that a stress value of ˜700 MPa is required. Although the origin of the stress in the stressor layer is intrinsic (originating from microstructure) and not due to coefficient of thermal expansion (CTE) stress, heating the stressor layer often has the effect of increasing the stress value. This is due to microstructural changes within the stressor layer that occur upon annealing and is irreversible. Localized heating is therefore contemplated to initiate fracture in the periphery of the area to be layer transferred. In other words, spontaneous spalling can be made to occur in small, selected regions to help initiate fracture, e.g., by increasing the thickness of the stress layer in these small selected regions. Localized heating can be performed using a laser, remote induction heating, or direct contact heating.

We have demonstrated controlled layer transfer of various source layers including Si, Ge, and GaAs directly onto a flexible membrane or foil handle (tape in FIG. 1) such as polyimide. Other art-known organic polymeric materials can also be used for the handle layer or foil, such as polyethylene terephthalae (PET), polycarbonates, ethylene polymers and copolymers, and fluorocarbon polymers and copolymers. This technique has the capability of transferring any processed semiconductor layers onto arbitrary substrates at room temperature in a manner that does not add significantly to the overall fabrication cost.

Another embodiment of this invention comprises creating a fracture plane which we also refer to as a strained layer below the surface of the source substrate. By creating the fracture plane (a region with weaker bonding than the source substrate), the spalling has been observed to occur preferentially within the fracture plane. This results in well-defined thickness of the exfoliated circuit layer, smoother fractured surfaces, improved reusability of the source substrate, and a convenient method of exfoliating pre-processed layers in a well-controlled manner. Examples of fracture planes, comprise buried strained epitaxial layers (strained layers) optionally weakened with hydrogen exposure, ion-implanted regions, or deposited layer interfaces obtained by processes well known in the art.

An example of a buried strained epitaxial layer comprises the growth of a single-crystal SiGe alloy layer on the surface of a Si substrate, followed by the growth of a Si capping layer. If this structure is exposed to hydrogen plasma, the hydrogen collects at the strained SiGe/Si interfaces and weakens the bonding at those interfaces. Preferential fracture along buried, strained, and hydrogenated (using plasma exposure) SiGe alloy layers grown on Si substrates has been successfully demonstrated. Additionally, the incorporation of boron in these SiGe alloy layers improves the efficiency of hydrogen trapping at the strained layer interface which we also refer to as a fracture plane.

Accordingly we grow a strained layer or fracture plane on a crystalline source substrate (using CVD, MBE, or even evaporation). As noted, this can comprise a strained layer or fracture plane comprising SiGe on Si (the SiGe can be boron doped or undoped), followed by growing a thick Si cap layer (on top of the strained layer or fracture plane that will be transferred, then subject the source substrate obtained to a hydrogen source capable of transporting hydrogen into it (hot acid, ion implant, plasma exposure, hot wire hydrogenation, and the like). The hydrogen attacks the subsurface strained bonds in the region of the strained layer or fracture plane interfaces, e.g., the interface between source substrate and strained layer or fracture plane thereby weakening the strained layer/source substrate interface. When we apply the controlled spalling technique described above, initiation, peeling, and fracture occurs with atomic scale precision at the weakened strained layer/source substrate interface. Because the material is weakened in the strained layer or fracture plane, fracture is easier (less force) and the metal layers, and/or can be thinner (less than about 3 um).

An example of deposited layer interface comprises single- or poly-crystalline layers deposited using evaporation, sputtering, molecular beam epitaxy, or chemical vapor deposition techniques such as UHVCVD, MOCVD, RPCVD or APCVD, performed in such a manner that the interface between the substrate and the deposited layer is imperfect. One such example is the growth or deposition of Si onto a Si substrate. Conditions may be chosen to leave a measurable quantity of residual oxygen, or carbon (or both) at the interface of substrate and layer which can serve as the location of preferred fracture. Hydrogenation can further weaken these interfaces as well.

What we describe here is the deposition of much thinner metal layers on the source substrate (over a factor of about 10× thinner than the prior art) at low temperature (less than about 300° C., typically about 100° C. compared to the prior art 900° C.), such that there is no spalling (film peeling) at this stage.

We have also demonstrated that employing a temporary adhesion layer like water, or a gel between the surface and a flexible membrane (i.e., foil handle or tape) followed by applying a force to flexible membrane away from source substrate can remove the surface layers and and they are free standing.).

We apply the mechanical force to the circuit layer in a direction away from the source substrate at an angle from about one degree up to about 180° to the plane of the surface of source substrate that is common with the circuit layer.

We have also demonstrated an advantage to propagating the fracture along the surface of a Si<001> substrate in any of the four ([100], [−100], [010], [0-10]) directions (orthogonal to the cleavage directions [110]). Fracture along these directions are much smoother and more consistent.

Thus, in one embodiment of the invention we deposit the stressor layer at a thickness less than about 10 um, but more than about 3 um of a metal, e.g., a metal comprising Ni on a source substrate stick the tape (i.e., handle layer) on the surface of the metal, and pull off the circuit layer and stressor layer. This works well on substrates comprising GaAs, Si, and Ge, as well as all substrates having crystal orientation <100> and <111>, although there is a pronounced improvement when using <111> oriented wafers (natural fracture plane) The improvements comprise smoother surfaces and thinner Ni layers for a given Ni stress value due to the reduced K_{IC} on the natural fracture planes.

Throughout this specification, abstract of the disclosure, and in the drawings, the inventors have set out equivalents, including without limitation, equivalent elements, materials, compounds, compositions, conditions, processes, structures and the like, and even though set out individually, also include combinations of these equivalents such as the two component, three component, or four component combinations, or more as well as combinations of such equivalent elements, materials, compositions conditions, processes, structures and the like in any ratios or in any manner.

Although we employ the term “force,” which is the product of mass multiplied by acceleration, we intend, for the purpose of this invention, to use the term “force” broadly to also include torque, or pressure, or tension, i.e., any mechanical effort or any type of mechanical energy applied to the layers to effect peeling where the force is applied by any prime mover known in the art such as an electric motor, or a heat engine, or fluid activated piston and cylinder means, or human effort, where the prime mover may be directly connected to or operatively associated with the layers or layer to be peeled, or connected or operatively associated with the layers or layer to be peeled through mechanical means comprising a rotating drum, or wheel, or lever, or wedge, or rack and pinion, or cylinder and piston means, and the art-known equivalents thereof, especially mechanical means that produce a mechanical advantage.

Additionally, the various numerical ranges describing the invention as set forth throughout the specification also includes any combination of the lower ends of the ranges with the higher ends of the ranges, and any single numerical value, or any single numerical value that will reduce the scope of the lower limits of the range or the scope of the higher limits of the range, and also includes ranges falling within any of these ranges.

The terms “about,” “substantial,” or “substantially” in any claim or as applied to any parameters herein, such as a numerical value, including values used to describe numerical ranges, means slight variations in the parameter. In another embodiment, the terms “about,” “substantial,” or “substantially,” when employed to define numerical parameter include, e.g., a variation up to five per-cent, ten per-cent, or 15 per-cent, or somewhat higher or lower than the upper limit of five per-cent, ten per-cent, or 15 per-cent. The term “up to” that defines numerical parameters means a lower limit comprising zero or a miniscule number, e.g., 0.001. The terms “about,” “substantial” and “substantially” also mean that which is largely or for the most part or entirely specified. The inventors also employ the terms “substantial,” “substantially,” and “about” in the same way as a person with ordinary skill in the art would understand them or employ them. The phrase “at least” means one or a combination of the elements, materials, compounds, compositions, or conditions, and the like specified herein, wherein “combination” is defined above. The terms “written description,” “specification,” “claims,” “drawings,” and “abstract” as used herein refer to the written description, specification, claims, drawings, and abstract of the disclosure as originally filed, or the written description, specification, claims, drawings, and abstract of the disclosure as subsequently amended, as the case may be.

All scientific journal articles and other articles, including Internet sites, as well as issued and pending patents that this written description mentions including the references cited in such scientific journal articles and other articles, including internet sites, and such patents, are incorporated herein by reference in their entirety and for the purpose cited in this written description and for all other disclosures contained in such scientific journal articles and other articles, including internet sites as well as patents and the aforesaid references cited therein, as all or any one may bear on or apply in whole or in part, not only to the foregoing written description, but also the following claims, abstract of the disclosure, and appended drawings.

Although the inventors have described their invention by reference to some embodiments, other embodiments defined by the doctrine of equivalents are intended to be included as falling within the broad scope and spirit of the foregoing written description, and the following claims, abstract of the disclosure, and appended drawings.

We claim

1. A process for imparting a controlled amount of stress in a semiconductor circuit that is part of a semiconductor substrate by inducing a mechanical fracture that propagates parallel to the surface of said substrate, and below said circuit and laterally, to produce a thin flexible circuit, comprising:
forming a semiconductor assembly by depositing a stressed metal film tensile stressor layer having a controlled amount of stress onto the surface of an individual or array of processed or completed circuits on a semiconductor substrate;
establishing an equilibrium fracture depth in said substrate extending below electrically active regions of said circuit layer;
applying a foil handle to said assembly and pulling said foil handle away from said assembly to harvest said circuit layer by inducing said fracture at said equilibrium fracture depth to produce a residual substrate that is thinner than said substrate and that incorporates said circuit layer;
wherein said circuit layer is under compressive strain and the amount of said compressive strain in said circuit layer is changed by modifying said stressor layer or said residual substrate.

2. The process of claim 1 comprising increasing the amount of said compressive strain in said circuit layer comprising reducing the thickness of said residual substrate.

3. The process of claim 1 comprising reducing the amount of compressive strain in said circuit layer comprising reducing the thickness of said stressor layer.

4. The process of claim 1 comprising substantially removing all of said stressor layer followed by deposition of a compressive stressor layer in place of said stressor layer to convert said compressive strain in said circuit layer into tensile strain.

5. The process of claim 1 wherein said fracture comprises a combination of a type I and type II fracture

6. The process of claim 1 wherein said foil handle is adhesively applied to said stressor layer.

7. The process of claim 1 wherein said stressor layer comprises a metal layer having a high yield stress.

8. The process of claim 1 comprising adjusting said stressor layer metal film thickness and stress to ensure proper fracture trajectories through preferred regions in said substrate comprising the provision of buried oxide interfaces or weakened layers in said substrate.

9. The process of claim 1 wherein said semiconductor circuit comprises a SOI circuit.

10. The process of claim 1 wherein said semiconductor circuit comprises a SOS circuit.

11. A process for imparting a controlled amount of stress in a semiconductor circuit that is part of a semiconductor substrate by inducing a mechanical fracture that propagates parallel to the surface of said substrate, and below said circuit and laterally, to produce a thin flexible circuit, comprising:
forming a semiconductor assembly by depositing a stressed metal film tensile stressor layer having a controlled amount of stress onto the surface of an individual or array of processed or completed circuits on a semiconductor substrate,;
establishing an equilibrium fracture depth in said substrate extending below electrically active regions of said circuit;
defining at lest one individualized circuit layer above said fracture by dividing it before fracture into at lest one preselected region or preselected regions by trenches surrounding said individualized circuit; the depth of said trenches being substantially similar to the equilibrium fracture depth;
applying a foil handle to said assembly and pulling said foil handle away from said assembly to harvest said individualized circuit layer by inducing said fracture at said equilibrium fracture depth to produce a residual substrate that is thinner than said substrate and that incorporates said circuit layer;
wherein said circuit layer is under compressive strain and the amount of said compressive strain in said circuit layer is changed by modifying said stressor layer or said residual substrate.

12. The process of claim 11 comprising increasing the amount of said compressive strain in said circuit layer by reducing the thickness of said residual substrate.

13. The process of claim 11 comprising reducing the amount of compressive strain in said circuit layer by comprising reducing the thickness of said stressor layer.

14. The process of claim 11 comprising substantially removing all of said stressor layer followed by deposition of a compressive stressor layer in place of said stressor layer to convert said compressive strain in said circuit layer into tensile strain.

15. The process of claim 11 wherein said fracture comprises a combination of type I and type II fracture

16. The process of claim 11 wherein said foil handle is adhesively applied to said stressor layer.

17. The process of claim 11 wherein said stressor layer comprises a metal layer having a high yield stress.

18. The process of claim 11 comprising adjusting said stressor layer metal film thickness and stress to ensure proper fracture trajectories through preferred regions in said substrate comprising the provision of buried oxide interfaces or weakened layers in said substrate.

19. The process of claim 11 wherein the depth of said trenches comprises a depth that is substantially twice the thickness of said stressor layer.

20. The process of claim 11 wherein said stressor layer is deposited onto said surface of said substrate so that said trench provides an efficient initiation and termination point of fracture, followed by removing said preselected regions independently from each other.

21. The process of claim 20 wherein said stressor layer is deposited onto said surface of said substrate by selective deposition in said preselected region or regions.

22. The process of claim 20 wherein said stressor layer is deposited onto said surface of said region-containing substrate by blanket layer deposition in said preselected region or regions.

23. The process of claim 11 wherein said preselected region or regions possess residual strain due to said stress transfer from said stressor layer to said circuit layer and controlling the magnitude and sign of said strain by post circuit stressor layer removal processing prior to bonding and packaging said circuit.

24. The process of claim 11 comprising increasing the amount of said compressive strain in said circuit layer comprising reducing the thickness of said residual substrate.

25. The process of claim 11 comprising reducing the amount of compressive strain in said circuit layer comprising reducing the thickness of said stressor layer.

26. The process of claim 11 comprising substantially removing all of said stressor layer followed by deposition of a compressive stressor layer in place of said stressor layer to convert said compressive strain in said circuit layer into tensile strain.

27. The process of claim 11 wherein said semiconductor circuit comprises a SOI circuit.

28. The process of claim 11 wherein said semiconductor circuit comprises a SOS circuit.

29. The process of claim 1 comprising a barrier layer between said stressor layer and said individual or array of processed or completed circuits

30. The process of claim 11 comprising a barrier layer between said stressor layer and said individual or array of processed or completed circuits

31. A product made by the process of claim 1.

32. A product made by the process of claim 11.
